(19) United States
(12) Patent Application Publication
(10) Pub. No.: US 2007/0128748 A1
(43) Pub. Date: Jun. 7, 2007

(54) Microreplication of transitory-image relief pattern based optically variable devices

(76) Inventor: Yit-Shun Leung Ki, Cointrin (CH)

Correspondence Address: NIXON & VANDERHYE, PC, 901 NORTH GLEBE ROAD, 11TH FLOOR, ARLINGTON, VA, 22203, US

(21) Appl. No.: 10/588,291

(22) PCT Filed: Jan. 24, 2005
(86) PCT No.: PCT/IB05/50264

§ 371 Date: Aug. 4, 2006

(30) Foreign Application Priority Data
Feb. 6, 2004 (CH) PCT/CH04/00070

(51) Int. Cl. H01L 21/00

(52) U.S. Cl. 438/29; 438/48

(57) ABSTRACT

The invention concerns a method for the replication by hot-embossing, hot-stamping or plastic injection moulding of an optically variable transitory image relief pattern characterized by the use of a Silicon origination shim fabricated through a micromachining process. The invention also comprises objects and structures obtained according to said method.

### FIELD OF THE INVENTION

The invention relates to the replication, by moulding, hot embossing or other comparable techniques, of an optically variable transitory-image relief pattern. The resulting, microreplicated, optically variable relief pattern is destined for, but not limited to use as a marking for the decoration, protection and end-customer authentication of branded products.

### PRIOR ART

Several solutions are currently available for the decoration, protection and customer authentication of branded products. They include: (i) offset printing based techniques for applying logos such as thermal pattern transfer and screen printing, (ii) security printing techniques such as intaglio printing with security inks, (iii) serialised, machine readable markings such as bar codes and finally (iv) optically variable markings, conventionally denoted as optically variable devices (OVDs) such as holographic seals and diffractive or interference elements. Each of these techniques addresses one or more of the following three principal reasons that one would want to mark a product, which are; brand visibility, authentication of origin and product tracking and tracing.

Optically variable devices or OVDs can be defined as markings, the visual aspects of which exhibit change when observed from different viewing angles. OVDs are increasingly used for the marking of goods and documents because they are—in contrast with printed labels—impossible to reproduce using widely available scanning or photocopying equipment, whether colour or monochrome and regardless of equipment resolution. Indeed copies obtained by such methods lose all the optically variable characteristics of the original due to the fixed viewing angle from which any given copy of the OVD can be made. In addition to the security with respect to scanning and colour printing equipment provided by OVDs as described above; OVDs provide additional security through the high technological barriers to counterfeiting for reasons which will rapidly become apparent below.

Optically variable effects can be obtained through a variety of methods widely reported in the public domain in textbooks such as “Optical Document Security” by Rudolf van Renesse (2^{nd} Ed. Artech House Publishers, Boston 1998), on the internet (http://pffc-online.com/ar/paper_dovids_functional_beauty/index.html) and disclosed in numerous patents such as JP411291610, U.S. Pat. No. 4,033,059, U.S. Pat. No. 4,721,217, or U.S. Pat. No. 6,296,281. An exhaustive list comprises: (i) diffractive devices such as holograms and interference or electron-beam generated elements, (ii) latent or transient image relief patterns, (iii) liquid crystal polymers and (iv) optically variable inks. Whereas the latter two are in a class of their own due to inherently chemical nature of the optically variable effects displayed; diffractive elements rely on substantially similar technological solutions to achieve optical variability. Specifically, they are always based on one or more physically imprinted relief patterns rendered optically variable by the interference of the light waves diffracted by the spacing of said relief patterns in the case of holograms and interference elements or by the dissimulation or appearance of various portions of the pattern made evident by the viewing angle of the observer with respect to the diffractive grid.

The mass production of markings, typically in the form of adhesive labels, incorporating the diffractive security features previously described, requires the reproduction of the imprinted relief on a plastic substrate on the basis of a production shim incorporating the negative of the desired relief. The exact replication process involves—in a first step called origination—the realisation of an initial master pattern on a suitably photosensitive substrate through holography, diffractive interference lithography or e-beam lithography. The origination master thus obtained is unsuitable for mass-replication and is therefore copied through successive electroforming steps onto a more suitable Nickel production shim used for replication.

Regardless of the patterning method used diffractive devices require high-precision techniques such as electron beam lithography for the realization of the image pattern using a grid fine enough to diffract light (typically 300-1000 nm). Furthermore, due to the shallowness of the imprinted relief the resulting marking layer requires additional layer structures for the protection, the visibility and the application of the desired optically variable devices as described, for instance, in PCT patent application WO 02/00445 A1. From a practical standpoint, this essentially limits diffractive devices to replication by roll-embossing on plastic sheet in order to obtain mass-produced markings in a format suitable for the application of the protective and visibility-enhancing layers previously mentioned. Finally, the close spacing of the relief pattern elements, the resulting markings always diffract light resulting in a characteristic and occasionally undesirable irridescent hue.

The aforementioned difficulties introduce a high technological barrier to the successful production of diffractive security markings, which renders them almost impervious to attempts at copying but at the same time is costly and somewhat inflexible.

Of particular interest are latent and transient image relief patterns, described in U.S. Pat. No. 4,033,059 or U.S. Pat. No. 6,296,281 typically reproduced on bank notes and other documents of value and commonly applied through the use of ink by steel intaglio printing. Steel intaglio printing infrastructure is expensive, however the intaglio shim, typically a cylindrical steel drum incorporating laser machined relief pattern negatives, is extremely durable allowing the replication through inking of a very large number of markings. This method however presents the disadvantage of being appropriate only for marking on paper or thin and flat plastic sheets and the additional drawback of requiring that a large number of identical markings be produced from a given shim due to its expense. Finally, the resolution of conventional laser machining, limits the resolution of the image patterns to approximately 300 dpi.

Micromachining technology as used in the technical field of Micro electromechanical systems (MEMS), offers interesting possibilities for many areas of application where fine resolutions and precise, micrometer-scale control of structural dimensions are required. As a result a wide range of industrial machinery and technologies have been developed to exploit these possibilities, in particular on Silicon substrates. This technology, although considerably cheaper than e-beam lithography based techniques, remains expensive due to the very small production runs of sensors and other devices it is commonly used to fabricate. The microreplication of micromachined master objects has been suggested more recently as a path to eliminating a large portion of the cost associated with micromachining. The present invention evokes the practicality of applying micromachining technology to the fabrication of OVD master shims. Such an application is typically non-obvious to Silicon micromachining specialists since developments in that field concentrate almost exclusively on the realization of functional devices such as physical sensors and actuators. It is equally non-obvious to OVD and DOVID specialists since the latter subject springs from the technical field of laser holography and development there has been limited to finding a technology—in their case e-beam lithography—with a sufficiently high spatial resolution to exploit holographic and diffraction techniques. Finally it is not sufficient to merely combine the two ideas, for micromachining is akin to traditional mechanical machining in the sense that it is merely a tool which must be properly employed to arrive at a given end.

The possibility of employing A Silicon micromachining-based process for the fabrication shims to be used for the hot-embossing of optical components such as wave guides and optical fiber casings is indeed not novel having been disclosed for example in PCT application WO95/22448. The method disclosed in WO95/22448 displays several drawbacks with respect to application for the replication of optically variable devices. Apart from the fact that OVDs and transitory-image relief patterns are not specifically referred to in the disclosure, its principal drawback is that it is far too general and thus complex for the application which is the object of the present invention, the process presented taking several full days to complete. Furthermore, the method disclosed in WO95/22448 does not exploit the full range of optically variable characteristics conceivable upon careful consideration of the various micromachining methods available, which are by no means limited to Silicon substrates for example. Finally the shims described in WO95/22448 can be used only for embossing and do not display the properties required for replication using alternative methods commonly utilized in the field of marking and brand authentication, namely hot stamping and injection moulding.

### SUMMARY OF THE INVENTION

The invention consists of a novel method of replicating optically variable transitory image relief patterns in (but not limited to) plastic, by hot embossing, stamping or injection moulding through the use of a shim prepared through the judicious use of robust micromachining techniques. In reference to the replication method described in detail previously whereby an origination shim is transformed by successive electroforming steps onto a Nickel production shim, which is then be used for replication; in the present invention, the origination master is obtained through a micromachining process on a suitable substrate such as Silicon for example. This technique is used to originate and subsequently, to obtain Nickel production shims containing transitory image type optically variable devices. It is this combination of three distinct technologies and techniques namely; (i) origination by micromachining, (ii) transitory-image type optically variable relief patterns and (iii) replication through electroforming onto a Nickel production shim which the present patent application seeks to protect.

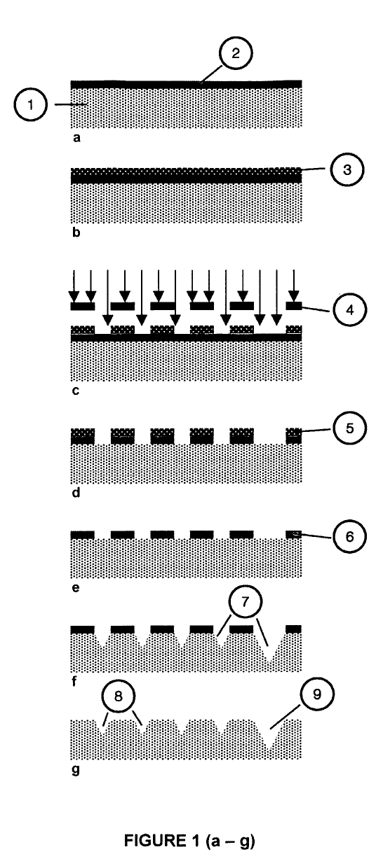

In accordance with the present invention, the origination shim may be a piece of Silicon monocrystal, micro-machined using a method including one or more distinct wet chemical or dry and plasma-assisted chemical etching steps of the Silicon, through a Silicon oxide (SiO₂) or Silicon nitride (Si₃N₄) thin-film masking layer patterned in a previous step by photolithography and wet or dry plasma-assisted chemical etching. Through the use of this method the negative of the relief pattern structures disclosed in U.S. Pat. No. 4,033,059 (FIGS. 1, 6, 9, 12 and 16) and presently pertaining to the public domain can be realized in the Silicon origination shim, which can now be used to reproduce optically variable transitory image relief patterns through the micro-replication process described previously. For example the resulting Nickel production shim drawn from the Silicon origination master can be used; as an embossing shim for the hot embossing of transitory-image OVDs in thermoplastics, a stamping shim for the hot-stamping of transitory-image OVDs in metallic foils or integrated into a plastic mould for the production—by injection moulding—of plastic parts incorporating an optically variable transitory image marking.

The fabrication process used to obtain a Silicon shim in accordance with the present invention is specifically designed for the replication of transitory-image OVDs. It not only addresses, insofar as possible, the disadvantages inherent to the fabrication of shims for the replication of DOVIDs but also allows, the replication of various novel transitory image relief pattern-based OVD types not currently conceivable in a mass-produced industrial setting because of the time required to make a shim incorporating these effects using conventional methods.

Specifically, a very large number of relief elements of which the larger relief pattern is composed can be structured during substantially the same steps using Silicon micromachining in comparison with for instance laser machining techniques used for steel intaglio printing. This is because with conventional techniques such as laser machining or electron-beam lithography, each of the relief elements must be sequentially written onto the shim substrate. To illustrate the time saved, for a relief pattern consisting of 1,000,000 relief elements and allowing 0.2 s for the individual writing or each element, it would require nearly three whole days to write the entire relief pattern. By comparison, the equivalent Silicon shim with 1,000,000 relief elements can be realized in less than four hours.

The method presented here to reproduce transitory-image OVDs is thus less time-consuming by orders of magnitude in comparison with conventional methods.

A relief pattern replicated using a Silicon shim can exhibit a relief depth between 0.5 and 100 μm and a relief spacing, or register as tight as 1 μm. By comparison, shims for DOVID replication, obtained by holography, interference lithography or electron-beam lithography have a typical relief depth and spacing considerably less than 1 μm. The deeper relief of the Silicon shim has two advantageous consequences. The first is that the relief is sufficiently deep to render the resulting optically variable effects clearly visible to the naked eye without recourse to the additional metallic layers necessary to render DOVIDs apparent. The second consequence is that OVDs replicated using a Silicon shim are much more resistant to mechanical wear due to the deeper relief.

The OVD replication method presented here, through the use of a micromachined Silicon origination shim, allows a single (as opposed to multiple) layer structure and even direct application on the object to be marked by being visually apparent and more resistant to mechanical wear due to deeper relief. It is thus addresses visibility and resistance issues of OVDs while simplifying the application process.

A further characteristic of OVDs replicated from a Silicon origination shim, is that the feature size and spacing of the relief elements, as well as their disposition is entirely selectable. Thus light diffraction does not occur except from extremely acute angles of vision, or occurs only in regions of the motif where one chooses to apply a very tight relief register. By comparison, conventional DOVIDs always diffract light and indeed the optically variable effects displayed by the latter often depend on this diffractive property. This gives conventional DOVIDs their characteristic irridescent rainbow-like hue. In contrast,

Transitory image relief patterns replicated from a Silicon origination shim are thus better suited than DOVIDs for the marking of objects, when the marking should not, for aesthetic reasons, display the irridescence caused by light diffraction. Furthermore, transitory image relief patterns replicated from a Silicon origination shim can incorporate iridescent and non-irridescent subregions while the entire image retains an optically variable character. This latter feature improves the counterfeit resistance of markings replicated according to the present invention.

In addition to addressing the issues above, the present invention also presents inherent advantages which are entirely novel within the context of transitory image relief pattern-based OVDs. Indeed in conventional OVDs of this type as described in U.S. Pat. No. 4,033,059 or in U.S. Pat. No. 6,296,281 optically variable characteristics are obtained through the spatial disposition of elements having a relief perpendicular to the plane of the image. With the present invention, for each of the patterns described in U.S. Pat. No. 4,033,059, an optically variable effect can be obtained in addition to those caused merely by the spatial disposition and relief of the optical elements if the wet-etching methods disclosed below are used. Indeed wet-etching, using for example Potassium Hydroxide (KOH) or Tetra Methyl Ammonium Hydroxide (TMAH), of the bulk Silicon substrate is etch plane selective. Thus the cross-section of the relief elements reproduced from the Silicon shim can be made—through alignment of the relief pattern with respect to the crystal planes of the Silicon—to be perfectly triangular with atomically smooth faces corresponding to the <111> crystallographic planes exposed by wet etching in the shim. The smoothness of the faces acts as a mirror allowing a specular reflection induced contrast switching effect dependent upon the viewing angle of the observer and the incident light.

A further inherent advantage of the present invention relates to the aforementioned characteristic whereby a very large number of relief elements are structured simultaneously. Indeed, this characteristic opens many interesting possibilities when the relief elements forming the larger transitory image relief pattern are composed of discrete shapes, as described for example in U.S. Pat. No. 6,296,281 as opposed to what substantially amounts to long ridges as described in U.S. Pat. No. 4,033,059. Such relief patterns have been insufficiently considered to date, probably because conventional methods cannot write very large numbers of relief elements within a reasonable time frame. In accordance with the present invention, a novel type of relief structure presenting several optically variable effects and based on short interleaved prism-like relief elements (PLREs) is claimed. This novel relief structure will be described in detail in the next section.

Finally, although the Silicon wet etching technique described above for the origination of transitory image relief patterns is a very rapid and cost effective method. It is by all means not the only micromachining method which could be used. A non-exhaustive list of other similar methods composed of combinations of photolithography, an appropriate masking layer and wet or dry etching is provided in the detailed description of the invention below.

### DETAILED DESCRIPTION

In accordance with the present invention, a Silicon origination shim is understood to mean an essentially flat object on which the physical negative of the relief elements composing the desired transitory image relief pattern to be replicated has been realized. For example, a V-shaped groove on the shim will correspond to a ridge-shaped relief element of pyramidal cross section on the replica. In accordance with the present invention, micromachining methods developed specifically to manufacture the negative of the relief elements necessary to obtain a series of well-known transitory image optically variable effects as described in U.S. Pat. No. 4,033,059 for instance, as well as a new type of transitory image relief pattern, are described in detail below.

In its most basic embodiment and in accordance with the present invention, a Silicon origination shim destined for the microreplication of transitory image relief patterns is obtained through a micromachining process, essentially derived from anisotropic, wet etchant-based, methods for the realization of V-grooves as described for instance in EP0472702 or again in the textbook “Fundamentals of Microfabrication: The Science of Miniaturization” (M. Madou, 2^{nd} ed., CRC press) which are well known in the technical field of Silicon micromachining. The full process for this embodiment is illustrated in FIGS. 1a-1g, where each subfigure represents a cross-sectional view of the Silicon substrate at different consecutive steps in the processing. The bulk substrate (1) from which the origination shim is made is a Silicon monocrystal wafer whose principal faces are parallel to the <100> crystallographic planes thereof and onto which a full etch-masking layer (2) consisting of Silicon dioxide (SiO₂) or Silicon nitride (Si₃N₄) has been formed. A full layer of photosensitive resin (photoresist) (3) is applied onto the etch-masking layer and insolated through a photomask (4) such that the photoresist is selectively removed in those areas corresponding to the subsequent location of relief element negatives on the shim after development of the photoresist. The aforementioned method of photoresist patterning using a photomask is commonly referred to as photolithography. The patterned photoresist layer (5) forms a selective mask through which the etch mask (2) can in turn be patterned either by wet etching in for example Hydrofluoric acid (HF or NH₄/HF) based solutions or by dry etching using for example CF₄ chemistry. The aforementioned etch-mask patterning step is usually followed by a cleaning step in which excess photoresist is removed for instance by immersion in an organic solvent bath or by exposure to a high-power Oxygen plasma. In a subsequent process step, the bulk substrate patterned using the process steps defined above is now immersed in a wet-etchant—composed for example of Potassium Hydroxide (KOH) or of Tetra-Methyl Ammonium Hydroxide (TMAH). Said wet-etchant need only have the particular property of etching the <100> crystallographic planes of the Silicon exposed by the patterned etch-masking layer (6) at a much higher rate than the corresponding <111> crystallographic planes of the Silicon at a given wet-etchant concentration and temperature. Typically for a KOH aqueous solution at a concentration of 40% by volume of KOH and at a temperature of 60° C., the etch rate ratio between <100> and <111> planes is approximately 100 which is suitable for the purposes of the present invention. The substrate is immersed in the aforementioned wet-etchant bath for such a time as is necessary to form V-grooves (7) in the bulk Silicon underneath the largest etch-masking layer openings, the flanks of the V-grooves corresponding to the <111> family of crystallographic planes in the Silicon. By virtue of its anisotropic nature, as described above, the etching process is greatly slowed down once a V-groove is formed under any given etching-mask opening. In particular smaller etching mask openings will result in shallower V-grooves (8) than larger ones (9) and consequently V-grooves of substantially different depths can be formed in the same wet etching step. The next step in the micromachining process consists of totally removing any remaining portions of the etch-masking layer by immersion in, for instance, a bath composed of an aqueous HF solution. The bulk substrate, now stripped of its etching-mask layer can be diced using mechanical sawing or some other equivalent technique to obtain shims of almost any desired shape, each containing the negative of a transitory image relief pattern. A portion of photomask used to obtain one of the types of transitory image relief pattern described in U.S. Pat. No. 4,033,059 is illustrated in FIG. 2, where the openings in the mask are represented by dark horizontal (10) or vertical (11) lines. In accordance with the present invention, the V-groove shaped relief elements composing the transitory image are formed in the Silicon substrate, at the location of each mask opening in the figure.

The actual method subsequently used to replicate the said transitory image relief pattern from the shim described here can consist of processes necessary for microreplication using hot-embossing, hot-stamping or moulding. Although the origination shim can be used directly for the replication of a small number of markings, typically, the origination shim obtained may be used to plate-out a more durable and resistant Nickel production shim through successive electroplating operations in a suitable bath. The use of a production shim electroplated from the origination shim is suitable for most microreplication methods such as hot-embossing, hot stamping. The production shim may also be used as a mould-insert for the marking of injection moulded objects. Finally for steel intaglio printing, it would be necessary to provide orifices in the production shim to accommodate ink injection. These methods are well known in the technical field of microreplication and do not pertain to the present invention.

In accordance with the present invention, the “single wet etching step” method described above allows the patterning of a Silicon origination shim containing the negative of relief elements, which can be of different depths and which are formed during the same micromachining process. Said relief elements can be disposed spatially at will on the photomask, in such a way that, at the end of the entire process described above, the replicated pattern will consist of distinguishable foreground and background areas which cooperate to form the transitory images described in FIGS. 6,7,8, 12 and 13 of U.S. Pat. No. 4,033,059 or combinations thereof. This first embodiment can also be used to realize transitory image relief patterns based on PRLEs as described in detail below. Finally, the <111> planes forming the sides of the V-groove relief element negatives on the shim, when replicated, form a mirror-like surface which yields a further optically variable contrast-switching effect between foreground and background relief patterns in comparison to those claimed by U.S. Pat. No. 4,033,059 or U.S. Pat. No. 6,296,281. This latter effect is caused by the specular reflection of the incident light off the <111> planes towards the observer.

In a further embodiment of the present invention, a fabrication process requiring two photomasks and two wet-etching steps is described below to obtain a Silicon origination shim for microreplication of a transitory image relief pattern of the type described in FIGS. 1-4 of U.S. Pat. No. 4,033,059. In this second embodiment, the bulk substrate consists also of a <100> oriented Silicon wafer coated with a suitable etch-masking layer as previously described. In a first photolithography step portions of the etch-masking layer are exposed. The etch-masking layer is then partially thinned in those exposed portions through for instance a timed etching step. After the aforementioned mask-thinning step, the remaining photoresist is completely removed from the substrate as described previously. A second photolithography step, using a second photomask, is then performed such that different portions of the etch-masking layer—which can be adjacent and contiguous to the portions thinned in the previous process steps—are completely removed by, for example wet etching. This step is followed by a cleaning step in which all the photoresist remaining after the removal of portions of the etching mask is dissolved. The etching mask now consists of areas where it has been completely removed, adjacent areas where it has been partially thinned and everywhere else of areas where it has retained its original thickness. The bulk substrate is now immersed in a wet-etchant having the properties previously described for such a time as necessary for the bulk Silicon to be etched into a U-shaped groove with flanks corresponding to the <111> planes of the monocrystal. The etching mask layer is now etched for a second time such that it is completely dissolved in the areas where it had been only thinned during the first photolithography and etching steps. The bulk substrate now consists of, areas where the Silicon has been etched in to a U-shaped groove, adjacent areas where the etching mask layer was removed during the previous process step to expose the original surface of the Silicon wafer and everywhere else of areas where the etching mask subsists albeit thinned compared to its original thickness. The bulk substrate is now immersed in wet etchant for a second time such that the areas containing U-shaped grooves are further etched until the <111> planes on the flank meet to form a V-shaped groove. From this point forward, the bulk substrate is stripped of all remaining etching mask material and can be diced into individual shims as described earlier for the first embodiment of this invention.

In accordance with the present invention the “two wet-etching step” method described above allows the patterning of a Silicon origination shim containing the negative of relief elements in which adjacent and contiguous portions of any of said elements can have two substantially different depths. The aforementioned relief elements can be disposed spatially at will on the two photomasks, in such a way that, at the end of the entire process described above, the replicated pattern will consist of distinguishable foreground and background areas which cooperate to form the transitory images described in FIGS. 1-4 of U.S. Pat. No. 4,033,059. In addition, all of the transitory image relief patterns which can be realized with the heretofore described embodiments of the present invention can be combined on the same Silicon origination shim simultaneously in the fabrication process just described for the second embodiment of the invention. This is done by placing the relief structure pattern of transitory images obtained using the first embodiment of the invention on the second photomask in the process described previously.

Although wet etching of the bulk Silicon is the preferred method for the structuring of the Silicon origination shim, the wet etching steps described in the previous two embodiments of the present invention can also be replaced, in a third embodiment of the present invention, by dry etching of the Silicon substrate using any of several suitable dry etch chemistries well-known in the technical field of Silicon micromachining. One such dry etching chemistry consists of using Sulphur Hexafluoride (SF₆) gas plasma. It must be noted however that replicated markings of shims fabricated using dry etching of the Silicon substrate do not exhibit the specular reflection effect previously described for replicas of wet-etched shims.

In a fourth and final embodiment of the present invention. Micromachining processes very similar to those described above may be used to obtain an origination shim, in materials other than Silicon, containing transitory-image type relief patterns. Indeed a wide variety of materials may be patterned with relief elements through a combination of photolithography and wet or dry etching through an appropriate selective masking material which. The resulting relief elements will differ from the analogous relief elements on Silicon as described above, only by their cross-section. A non-exhaustive list of techniques includes: Dry or wet etching in glass substrates through a photoresist or a Chromium mask and dry or wet etching of various metal substrates, including Aluminum and Copper through a photoresist mask.

In addition to the embodiments of the invention previously described, a novel transitory image relief structure which can be replicated through the use of a Silicon origination shim fabricated in accordance with the processes described by any of the embodiments of the present invention.

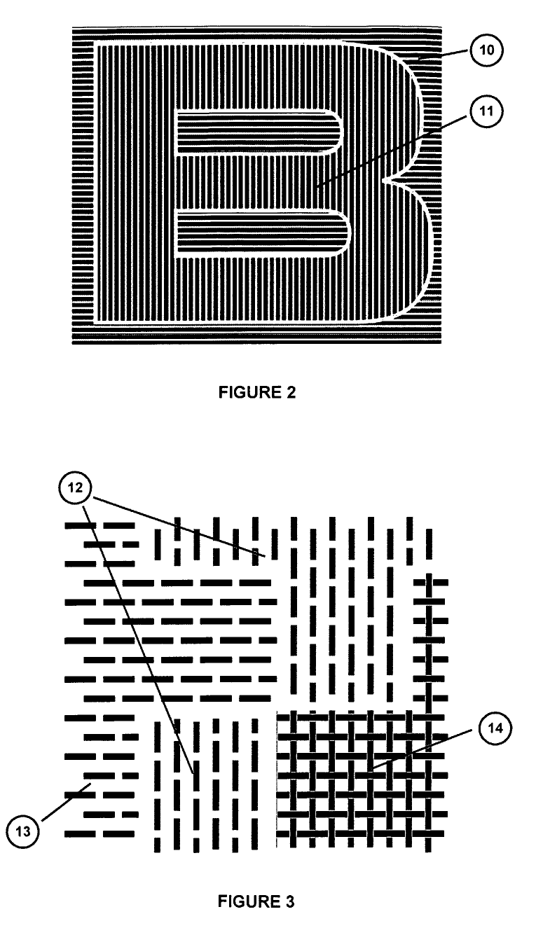

The transitory image relief pattern is composed of a large number of prism-like relief elements (PRLEs), each PLRE being characterized by relief as well as by being rectangular in shape if viewed from a direction normal to the plane of the image. The aspect ratio of the PRLEs is included between 3:1 and 50:1 with a typical length of the long side between 50 and 250 μm. In this relief structure (see FIG. 3), two sets of PLREs are defined in row-wise staggered grids with the elements of one set of PLREs rotated through 90° with respect to the second set such that if the two sets are placed together on the same substrate, the elements of the second grid fall in an exactly aligned and symmetrical fashion between the elements of the first grid. As illustrated in FIG. 3 and in accordance with the present invention, the three possible types of PLRE grid namely; a PLRE grid composed only of relief elements oriented as per the first set of relief elements (12), a grid composed only of relief elements oriented as per the second set of relief elements (13) and a third grid composed of combined first and second set relief elements (14); are assigned to separate portions—of which there may be more than three—of the image which make up the total relief pattern. The three types of grid and the portions of the image to which they are assigned cooperate to present (a) a contrast switching effect between areas covered by the first and second type of PLRE grid when the OVD is tilted and rotated through 90°, (b) a highlighting of the areas to which the combined grid is assigned when the OVD is viewed from directions essentially perpendicular to the plane of the image and (c) a specular reflection contrast switching effect off the imprint of the relief element faces representing <111> planes of wet-etched Silicon, the appearance of which is dependent upon a combination of viewing angle and incident light, typically made apparent by slight lateral rotations of the tilted image about the line of sight to the observer.

1. A method for replication by hot-embossing, hot-stamping, hot foil-stamping or plastic injection moulding of an optically variable transitory image relief pattern characterized by the use of an origination shim fabricated through a micromachining process involving successive photolithography, etch-mask layer patterning and bulk substrate etching steps.

2. A method according to claim 1 comprising bulk substrate wet chemical etching steps and wherein the bulk substrate consists of <100> oriented monocrystalline Silicon.

3. A method according to claim 1 comprising bulk substrate dry reactive-ion etching steps and wherein the bulk substrate consists of <100> or <111> oriented monocrystalline Silicon.

4. A method according to claim 1 characterized by a bulk substrate consisting principally of Silicon dioxide including but not limited to glass or quartz.

5. A method according to claim 1 characterized by a bulk substrate consisting of a metal or metal alloy including but not limited to Aluminium, Copper, Steel and alloys thereof.

6. A method according to claim 1 comprising a step consisting of the production of a Nickel shim obtained by copying said origination shim through successive Nickel electroforming steps.

7. A shim obtained according to claim 1.

8. A shim according to claim 7 through the use of which transitory image relief patterns displaying a contrast switch between foreground and background images when rotated through 90 at a fixed viewing angle offset to the normal can be replicated.

9. A shim according to claim 7 through the use of which a background transitory image relief pattern and a foreground transitory image relief pattern image can be replicated such that the foreground image relief pattern is hidden by the background relief pattern, when the replicated image is tilted away from the observer.

10. A shim according to claim 7 through the use of which a background transitory image relief pattern and a foreground transitory image relief pattern image can be replicated such that the foreground transitory image relief pattern, non-apparent when viewed perpendicular to the plane of the image replica, appears against the background relief pattern, when the replicated image is tilted away from the observer.

11. A shim according to claim 7 through the use of which prism-like relief elements (PLREs) define an image, subdivided into portions composed of either of three sub-types of PLRE array; one sub-type consisting of PLREs oriented in a given direction and arranged in a row-wise staggered grid, a second sub-type consisting of PLREs rotated by 90° in the same plane as the first subtype also arranged in a row-wise staggered grid and a third subtype combining both of the first two subtypes in such a way that the PLREs defining the second subtype are placed symmetrically in the interstices formed by the first subtype wherein said image displays various visual contrast switching effects between the portions of the image assigned to each of the PLRE array sub-types upon,
i) Rotation of the tilted image about the normal.
ii) Tilting of the image about the viewing angle.

12. A shim obtained according to claim 7 wherein said shim is fabricated during the same series of micromachining process steps, and from which a marking can be replicated combining optically variable effects comprising:
(a) transitory image relief patterns displaying a contrast switch between foreground and background images when rotated through 90 at a fixed viewing anile offset to the normal can be replicated;
(b) a background transitory image relief pattern and a foreground transitory image relief pattern image can be replicated such that the foreground image relief pattern is hidden by the background relief pattern, when the replicated image is tilted away from the observer;
(c) a background transitory image relief pattern and a foreground transitory image relief pattern image can be replicated such that the foreground transitory image relief pattern, non-apparent when viewed perpendicular to the plane of the image replica, appears against the background relief pattern, when the replicated image is tilted away from the observer; and
(d) prism-like relief elements (PLREs) define an image, subdivided into portions composed of either of three sub-types of PLRE array; one sub-type consisting of PLREs oriented in a given direction and arranged in a row-wise staggered grid, a second sub-type consisting of PLREs rotated by 90° in the same plane as the first subtype also arranged in a row-wise staggered grid and a third subtype combining both of the first two subtypes in such a way that the PLREs defining the second subtype are placed symmetrically in the interstices formed by the first subtype, wherein said image displays various visual contrast switching effects between the portions of the image assigned to each of the PLRE array sub-types upon,
i) Rotation of the tilted image about the normal.
ii) Tilting of the image about the viewing angle.

13. A transitory image structure characterized by the use of a shim obtained according to claim 7.

14. A transitory image structure according to claim 13 wherein the relief elements are defined by raised or depressed portions of a substrate.

15. A transitory image structure according to claim 13 wherein the relief elements are embossed in a substrate.

16. A transitory image structure according to claim 13 wherein the relief elements are hot-stamped on a substrate comprising two or more distinct layers.

17. A transitory image structure according to claim 13 wherein the relief elements comprise portions of ink.

18. A transitory image structure according to claim 13 wherein the relief elements are intaglio printed on a substrate.

19. An object carrying a transitory image structure according to claim 13.

20. An object according to claim 19 obtained by plastic injection moulding incorporating a transitory image structure for which the marking and the object are fabricated during substantially the same injection moulding step.
